(19) United States
(12) Patent Application Publication
(10) Pub. No.: US 2026/0082777 A1
(43) Pub. Date: Mar. 19, 2026

(54) DISPLAY PANEL AND DISPLAY APPARATUS

(71) Applicants: BOE Technology Group Co., Ltd., Beijing (CN); Chengdu BOE Optoelectronics Technology Co., Ltd., Chengdu, Sichuan (CN)

(72) Inventors: Dongjie WU, Beijing (CN); Kai ZHANG, Beijing (CN); Hailong YAN, Beijing (CN); Erlong SONG, Beijing (CN); Wenbo HU, Beijing (CN); Gang WANG, Beijing (CN); Kunyan SHI, Beijing (CN); Huaping SUN, Beijing (CN); Qi ZHANG, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 19/102,464

(22) PCT Filed: Apr. 17, 2024
(86) PCT No.: PCT/CN2024/088395

§ 371 Date: Feb. 10, 2025

(30) Foreign Application Priority Data
May 12, 2023 (CN) 202310539404.7

(51) Int. Cl. H10K 59/131; H10K 59/80

(52) U.S. Cl. CPC H10K 59/131; H10K 59/80521; H10K 59/8722; H10K 59/873

(57) ABSTRACT

A display panel has a through hole and an isolation region. The display panel includes a substrate, at least one first isolation structure located in the isolation region and arranged around the through hole, and a cathode layer extending to the isolation region. A first isolation structure includes a first isolation portion and a second isolation portion. An edge portion, close to a surface of the substrate, of the second isolation portion extends beyond the first isolation portion. In the isolation region, the first isolation structure divides the cathode layer into a first sub-portion and a second sub-portion. In a direction perpendicular to a boundary of the through hole, the first sub-portion and the second sub-portion are alternately arranged. The first sub-portion is located on a side of the second isolation portion away from the substrate. The second sub-portion is located on a side of the first isolation portion.

### CROSS-REFERENCE TO RELATED APPLICATIONS

This application is a national phase entry under 35 USC 371 of International Patent Application No. PCT/CN2024/088395, filed on Apr. 17, 2024, which claims priority to Chinese Patent Application No. 202310539404.7, filed on May 12, 2023, each are incorporated herein by reference in their entirety.

### TECHNICAL FIELD

The present disclosure relates to the field of display technologies, and in particular, to a display panel and a display apparatus.

### BACKGROUND

With the development of display technology, display apparatuses (such as mobile phones, notebook computers or tablet computers) are increasingly used in people's lives. Organic light-emitting diodes (OLEDs) have been widely used in the display field due to their advantages such as self-luminescence, low driving voltage, high luminous efficiency, fast response, and flexible display.

### SUMMARY

In an aspect, a display panel is provided. The display panel has a through hole and an isolation region surrounding the through hole. The display panel includes a substrate, at least one first isolation structure and a cathode layer. The at least one first isolation structure is located on the substrate, located in the isolation region, and arranged around the through hole. A first isolation structure includes a first isolation portion and a second isolation portion that are stacked; the first isolation portion is located between the second isolation portion and the substrate; an edge portion, close to a surface of the substrate, of the second isolation portion extends beyond the first isolation portion; and the first isolation portion is made of an insulating material. The cathode layer is located on the substrate and extends to the isolation region. In the isolation region, the first isolation structure divides the cathode layer into a first sub-portion and a second sub-portion; in a direction perpendicular to a boundary of the through hole, the first sub-portion and the second sub-portion are alternately arranged; the first sub-portion is located on a side of the second isolation portion away from the substrate; and the second sub-portion is located on a side of the first isolation portion.

In some embodiments, the display panel further includes a first planarization layer located between the substrate and the cathode layer. The first isolation portion and the first planarization layer are arranged in a same layer.

In some embodiments, the display panel further includes a passivation layer and a first planarization layer. The passivation layer is located between the cathode layer and the substrate. The first planarization layer is located between the passivation layer and the cathode layer. The first isolation portion includes a first sub-layer and a second sub-layer that are stacked in a direction away from the substrate; the first sub-layer and the passivation layer are arranged in a same layer; and the second sub-layer and the first planarization layer are arranged in a same layer.

In some embodiments, the display panel further includes a second source-drain metal layer located between the cathode layer and the substrate. The second isolation portion and the second source-drain metal layer are arranged in a same layer.

In some embodiments, the second source-drain metal layer includes a first metal layer, a second metal layer and a third metal layer that are stacked in a direction away from the substrate; the second isolation portion includes a first pad layer, a second pad layer and a third pad layer that are stacked in the direction away from the substrate; the first pad layer and the first metal layer are arranged in a same layer; the second pad layer and the second metal layer are arranged in a same layer; the third pad layer and the third metal layer are arranged in a same layer; and an edge portion of the first pad layer extends beyond the first isolation portion; and an edge portion of the third pad layer extends beyond the second pad layer.

In some embodiments, the edge portion of the first pad layer extends beyond the second pad layer.

In some embodiments, the display panel further includes a first inorganic encapsulation layer located on a side of the cathode layer away from the substrate and extending to the isolation region. The first inorganic encapsulation layer is in contact with a side surface of the first isolation portion, a surface of a portion of the first pad layer extending beyond the first isolation portion, a side surface of the second pad layer, and a surface of a portion of the third pad layer extending beyond the second pad layer.

In some embodiments, the at least one first isolation structure includes a plurality of first isolation structures, and the plurality of first isolation structures are arranged at intervals in the direction perpendicular to the boundary of the through hole.

In some embodiments, the display panel further includes a barrier wall structure located in the isolation region and arranged around the through hole. At least one of the first isolation structures is located on a side of the barrier wall structure close to the through hole, and at least one of the first isolation structures is located on a side of the barrier wall structure away from the through hole.

In some embodiments, the display panel further includes an inorganic insulating layer located between the substrate and the first isolation structure and extending to the isolation region. A surface of the inorganic insulating layer away from the substrate is provided with a plurality of separation grooves; the plurality of separation grooves are arranged around the through hole, are located in the isolation region, and are located on the side of the barrier wall structure away from the through hole; a portion of the inorganic insulating layer located between two adjacent separation grooves constitutes a protrusion; and a first isolation structure located on the side of the barrier wall structure away from the through hole is located on a side of the protrusion away from the substrate.

In some embodiments, the display panel further includes a first source-drain metal layer, a second source-drain metal layer and one or more second isolation structures. The first source-drain metal layer is located between the cathode layer and the substrate, and the first source-drain metal layer includes a fourth metal layer, a fifth metal layer and a sixth metal layer that are stacked in a direction away from the substrate. The second source-drain metal layer is located between the first source-drain metal layer and the cathode layer, and the second source-drain metal layer includes a first metal layer, a second metal layer and a third metal layer that are stacked in the direction away from the substrate. The one or more second isolation structures are located in the isolation area and are arranged around the through hole. A second isolation structure includes a third isolation portion and a fourth isolation portion that are stacked in the direction away from the substrate; the third isolation portion includes a fourth pad layer, a fifth pad layer and a sixth pad layer; the fourth isolation portion includes a seventh pad layer, an eighth pad layer and a ninth pad layer. The fourth pad layer and the fourth metal layer are arranged in a same layer; the fifth pad layer and the fifth metal layer are arranged in a same layer; the sixth pad layer and the sixth metal layer are arranged in a same layer; the seventh pad layer and the first metal layer are arranged in a same layer; the eighth pad layer and the second metal layer are arranged in a same layer; and the ninth pad layer and the third metal layer are arranged in a same layer. An edge portion of the sixth pad layer extends beyond the fifth pad layer; and an edge portion of the ninth pad layer extends beyond the eighth pad layer.

In some embodiments, the display panel further includes a passivation layer and a first planarization layer. The passivation layer is located between the first source-drain metal layer and the second source-drain metal layer. The first planarization layer is located between the passivation layer and the second source-drain metal layer. The second isolation structure further includes a fifth isolation portion disposed between the third isolation portion and the fourth isolation portion; the fifth isolation portion is arranged in a same layer as the first planarization layer, and/or arranged in a same layer as the passivation layer. An edge portion of the seventh pad layer extends beyond the fifth isolation portion.

In some embodiments, the display panel further includes a first inorganic encapsulation layer located on a side of the cathode layer away from the substrate and extending to the isolation region. The first inorganic encapsulation layer is in contact with a side surface of the fifth pad layer, a surface of a portion of the sixth pad layer extending beyond the fifth pad layer, a side surface of the eighth pad layer, and a surface of a portion of the ninth pad layer extending beyond the eighth pad layer. In a case where the second isolation structure further includes a fifth isolation portion, the first inorganic encapsulation layer is further in contact with a side surface of the fifth isolation portion and a surface of a portion of the seventh pad layer extending beyond the fifth isolation portion.

In some embodiments, the display panel further includes a barrier wall structure. The barrier wall structure is located in the isolation region and arranged around the through hole. At least one second isolation structure is disposed on a side of the barrier wall structure close to the through hole.

In some embodiments, the display panel further includes at least one third isolation structure, the at least one third isolation structure is disposed on the side of the barrier wall structure close to the through hole, and the second isolation structure is closer to the through hole than the third isolation structure.

In some embodiments, orthogonal projections, on the substrate, of the fourth pad layer, the sixth pad layer, the seventh pad layer and the ninth pad layer coincide with each other.

In some embodiments, the display panel further includes a first gate metal layer and a second gate metal layer that are stacked and disposed between the substrate and the first source-drain metal layer, a first pad block and a second pad block. The first pad block is arranged in a same layer as the first gate metal layer, is located on a side of the barrier wall structure close to the through hole, and is arranged around the through hole. An orthogonal projection of the first pad block on the substrate overlaps with an orthogonal projection of the second isolation structure on the substrate. The second pad block is arranged in a same layer as the second gate metal layer, is located on the side of the barrier wall structure close to the through hole, and is arranged around the through hole. An orthogonal projection of the second pad block on the substrate overlaps with the orthogonal projection of the second isolation structure on the substrate.

In yet another aspect, a display apparatus is provided. The display apparatus includes: the display panel as described in any one of the above embodiments and a cover plate. The cover plate is located on a side of the first isolation structure in the display panel away from the substrate.

In some embodiments, the display apparatus further includes a second pressure-sensitive conductive adhesive. The second pressure-sensitive conductive adhesive is located between the display panel and the cover plate, and the second pressure-sensitive conductive adhesive covers the display panel.

### BRIEF DESCRIPTION OF THE DRAWINGS

In order to describe technical solutions in some embodiments of the present disclosure more clearly, the accompanying drawings to be used in some embodiments of the present disclosure will be introduced briefly. However, the accompanying drawings to be described below are merely some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments;

FIG. 2 is a sectional view taken along the section line A-A in FIG. 1;

FIG. 3 is a structural diagram of a display panel, in accordance with some embodiments;

FIG. 4 is a sectional view taken along the section lines B-B and B′-B′ in FIG. 3;

FIG. 5 is a structural diagram of a first isolation structure, in accordance with some embodiments;

FIG. 6 is another sectional view taken along the section line B′-B′ in FIG. 3;

FIG. 7 is yet another sectional view taken along the section line B′-B′ in FIG. 3;

FIG. 8 is yet another sectional view taken along the section line B′-B′ in FIG. 3;

FIG. 9 is a structural diagram of a second isolation structure, in accordance with some embodiments;

FIG. 10 is a structural diagram of another second isolation structure, in accordance with some embodiments;

FIG. 11 is a structural diagram of yet another second isolation structure, in accordance with some embodiments;

FIG. 12 is a structural diagram of yet another second isolation structure, in accordance with some embodiments; and

FIG. 13 is yet another sectional view taken along the section line B′-B′ in FIG. 3.

### DETAILED DESCRIPTION

The technical solutions in some embodiments of the present disclosure will be described clearly and completely with reference to the accompanying drawings. However, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment,” “some embodiments,” “exemplary embodiments,” “example,” “specific example,” or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

The terms “first” and “second” are used for descriptive purposes only, and are not to be construed as indicating or implying a relative importance or implicitly indicating the number of indicated technical features. Thus, features defined with “first” or “second” may explicitly or implicitly include one or more of the features. In the description of the embodiments of the present disclosure, the term “multiple”, “a plurality of” or “the plurality of” means two or more unless otherwise specified.

In the description of some embodiments, the expression “connected” and derivatives thereof may be used. The term “connected” should be understood in a broad sense. For example, the term “connected” may represent a fixed connection, a detachable connection, or a one-piece connection, or may represent a direct connection, or may represent an indirect connection through an intermediate medium.

The phrase “at least one of A, B, and C” has the same meaning as the phrase “at least one of A, B, or C”, both including the following combinations of A, B, and C: only A, only B, only C, a combination of A and B, a combination of A and C, a combination of B and C, and a combination of A, B, and C.

The phrase “A and/or B” includes following three combinations: only A, only B, and a combination of A and B.

The phrase “applicable to” or “configured to” used herein has an open and inclusive meaning, which does not exclude devices that are applicable to or configured to perform additional tasks or steps.

The term such as “substantially” as used herein includes a stated value and an average value within an acceptable range of deviation of a particular value determined by a person of ordinary skill in the art, considering measurement in question and errors associated with measurement of a particular quantity (i.e., limitations of a measurement system).

The term such as “parallel,” “perpendicular,” or “equal” as used herein includes a stated condition and a condition similar to the stated condition. A range of the similar condition is within an acceptable deviation range, and the acceptable deviation range is determined by a person of ordinary skill in the art, considering measurement in question and errors associated with measurement of a particular quantity (i.e., the limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be that, for example, a difference between the two that are equal is less than or equal to 5% of either of the two.

It will be understood that, when a layer or element is referred to as being on another layer or substrate, it may be that the layer or element is directly on the another layer or substrate, or it may be that intermediate layer(s) exist between the layer or element and the another layer or substrate.

Exemplary embodiments are described herein with reference to sectional views and/or plan views that are schematic illustrations of idealized embodiments. In the drawings, thicknesses of layers and areas of regions are enlarged for clarity. Variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Thus, the regions shown in the accompanying drawings are schematic in nature, and their shapes are not intended to show actual shapes of the regions in a device, and are not intended to limit the scope of the exemplary embodiments.

The directional words such as “above”, “below”, “left” and “right” in the embodiments of the present disclosure are described based on angles shown in the accompanying drawings and should not be construed as limitations on the embodiments of the present disclosure.

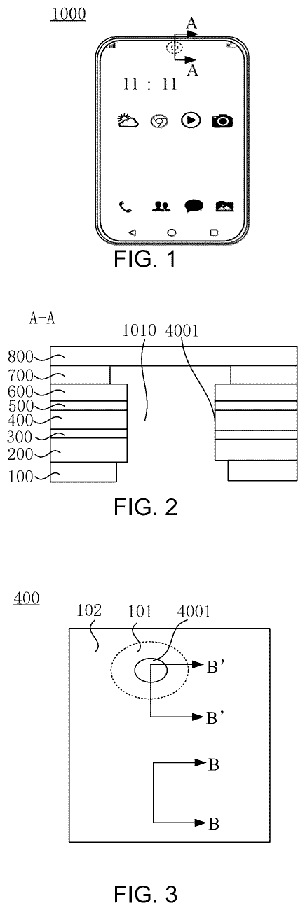

Some embodiments of the present disclosure provide a display apparatus 1000. As shown in FIG. 1, the display apparatus 1000 may be a device or apparatus for visually displaying electronic information. For example, the display apparatus 1000 may include one of a smart phone, a tablet computer, a notebook computer, a television, and a smart watch. For example, the display apparatus 1000 includes a smart phone.

The display apparatus 1000 may be an organic light-emitting diode (OLED) display apparatus, a quantum dot light-emitting diode (QLED) display apparatus, or an active matrix organic light-emitting diode (AMOLED) display apparatus. The embodiments of the present disclosure will be described by taking an example in which the display apparatus is an OLED display apparatus.

As shown in FIG. 2, the display apparatus 1000 includes a support layer 100, a back film 200, a first pressure-sensitive conductive adhesive 300, a display panel 400, a second pressure-sensitive conductive adhesive 500, a circular polarizer 600, a photosensitive adhesive 700 and a cover plate 800, which are sequentially stacked. The support layer 100 is used to support the display panel 400, and a material of the support layer 100 may include stainless steel or aluminum, which will not be listed one by one in the embodiments of the present disclosure. The back film 200 is used to reduce the risk of water and oxygen entering the display panel 400. The first pressure-sensitive conductive adhesive 300 is used to bond the display panel 400 and the back film 200, and the first pressure-sensitive conductive adhesive 300 covers the display panel 400. The second pressure-sensitive conductive adhesive 500 is used to bond the display panel 400 and the circular polarizer 600, and the second pressure-sensitive conductive adhesive 500 covers the display panel 400. The circular polarizer 600 is used to reduce the reflection of ambient light by the display panel 400. The photosensitive adhesive 700 is used to bond the circular polarizer 600 and the cover plate 800. The cover plate 800 is used to protect the display panel 400.

As shown in FIG. 2, the display apparatus 1000 is provided with a first hole 1010, and the first hole 1010 may be used to place a functional device. For example, the functional device is a device that can realize a specific function, such as a front camera assembly, a fingerprint assembly, a 3D face recognition assembly, an iris recognition assembly or a proximity sensor. The embodiments of the present disclosure will be described by taking an example in which the functional device is a front camera assembly.

As shown in FIG. 2, the first hole 1010 penetrates through the support layer 100, the back film 200, the first pressure-sensitive conductive adhesive 300, the display panel 400, the second pressure-sensitive conductive adhesive 500, the circular polarizer 600 and the photosensitive adhesive 700. Only the cover plate 800 is located above the front camera assembly, and the cover plate 800 has a high light transmittance (for example, the light transmittance is greater than 85%). The front camera assembly receives sufficient light, resulting in good imaging quality of the front camera assembly. The cover plate 800 may reduce the risk of the front camera assembly colliding with other objects, thereby reducing the risk of barrier wallage to the front camera assembly.

A shape of an orthogonal projection of the first hole 1010 on the cover plate 800 can be set according to actual needs. For example, the orthogonal projection of the first hole 1010 on the cover plate 800 may be circular, polygonal, fan-shaped, or irregular-shaped, which will not be listed one by one in the embodiments of the present disclosure. The embodiments of the present disclosure will be described by taking an example in which the orthogonal projection of the first hole 1010 on the cover plate 800 is circular.

In some embodiments, as shown in FIGS. 2 and 3, the first hole 1010 penetrates through the display panel 400 to form a through hole 4001. The display panel 400 has an isolation region 101 and a display region 102. The isolation region 101 surrounds the through hole 4001, and a part of the display region 102 surrounds the isolation region 101.

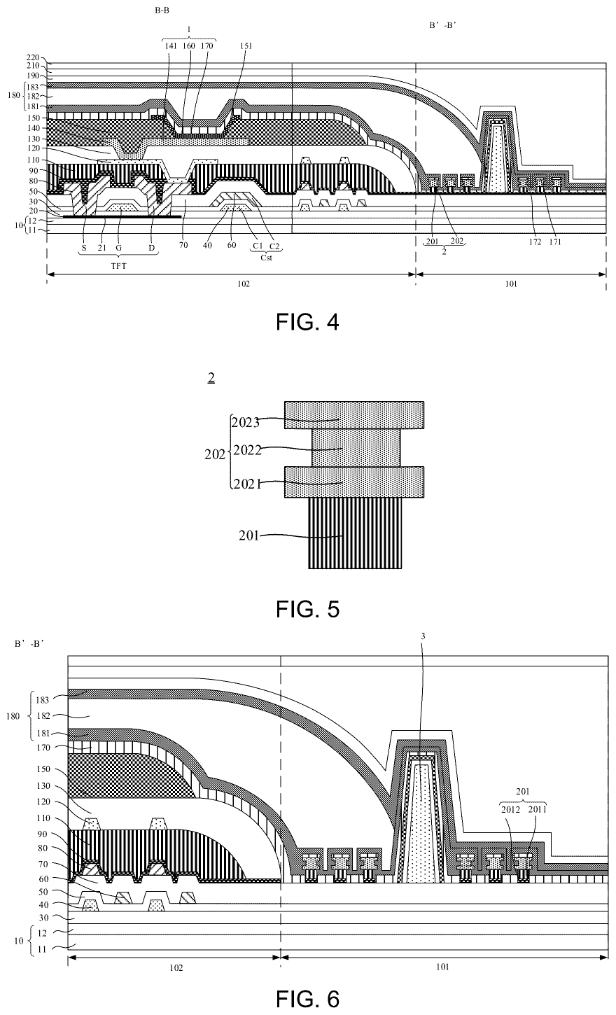

FIG. 4 is a diagram showing a stacked structure of film layers in a display panel. As shown in FIG. 4, the display panel 400 includes a substrate 10, and an active layer 20, a first gate insulating layer 30, a first gate metal layer 40, a second gate insulating layer 50, a second gate metal layer 60, an interlayer dielectric layer 70, a first source-drain metal layer 80, a passivation layer 90, a first planarization layer 110, a second source-drain metal layer 120, a second planarization layer 130, an anode layer 140, a pixel definition layer 150, a light-emitting functional layer 160, a cathode layer 170 and an encapsulation layer 180, which are arranged in a direction away from the substrate 10.

In some embodiments, as shown in FIG. 4, the substrate 10 may be a flexible substrate 10 or a rigid substrate 10. The rigid substrate 10 may be made of glass, and the flexible substrate 10 may be made of polyimide (PI). The substrate 10 may be of a single-layer structure or a multi-layer structure. For example, when the substrate 10 is of a multi-layer structure, the substrate 10 may include a base 11 and a buffer layer 12 disposed on the base 11. A material of the buffer layer 12 may include silicon oxide, silicon nitride, or silicon oxide and silicon nitride stacked together, which will not be specifically limited in the embodiments of the present disclosure.

The active layer 20 is located on the substrate 10, and the active layer 20 includes a plurality of active patterns 21. A material of the active layer 20 may include polysilicon or oxide material, which will not be listed one by one in the embodiments of the present disclosure. For example, the active layer 20 is made of an oxide material.

The first gate insulating layer 30 is located on a side of the active layer 20 away from the substrate 10. The first gate insulating layer 30 may be made of silicon oxide, silicon nitride, or silicon oxynitride, which will not be listed one by one in the embodiments of the present disclosure.

The first gate metal layer 40 is located on a side of the first gate insulating layer 30 away from the substrate 10. The first gate metal layer 40 includes a plurality of gates G and a plurality of first electrode plates C1. A material of the first gate metal layer 40 may include a material with excellent conductivity, such as Al, Ag, Cu, and Cr.

The second gate insulating layer 50 is located on a side of the first gate metal layer 40 away from the substrate 10, and the second gate insulating layer 50 may be made of the same material as the first gate insulating layer 30.

The second gate metal layer 60 is located on a side of the second gate insulating layer 50 away from the substrate 10, and the second gate metal layer 60 includes a plurality of second electrode plates C2. The second gate metal layer 60 may be made of the same material as the first gate metal layer 40. A first electrode plate C1 and a second electrode plate C2 constitute a capacitor Cst.

The interlayer dielectric layer 70 is located on a side of the second gate metal layer 60 away from the substrate 10. A material of the interlayer dielectric layer 70 includes silicon oxide, silicon nitride, silicon oxynitride, aluminum oxide or titanium oxide, which will not be listed one by one in the embodiments of the present disclosure.

The first source-drain metal layer 80 is located on a side of the interlayer dielectric layer 70 away from the substrate 10, and the first the source-drain metal layer 80 includes a plurality of sources S and a plurality of drains D. The first source-drain metal layer 80 may be made of the same material as the first gate metal layer 40. An active pattern 21, a source S, a drain D and a gate G constitute a thin film transistor (TFT).

The passivation layer 90 is located on a side of the first source-drain metal layer 80 away from the substrate 10. The passivation layer 90 may reduce the risk of water vapor and impurities in the air entering the first source-drain metal layer 80, thus reducing the risk of the first source-drain metal layer 80 being barrier wallaged. In this case, the passivation layer 90 may be made of the same material as the first gate insulating layer 30.

The first planarization layer 110 is located on a side of the passivation layer 90 away from the substrate 10. The first planarization layer 110 is used to make a surface of the passivation layer 90 away from the substrate 10 planar, which may reduce the risk of unevenness of the surface of the passivation layer 90 away from the substrate 10 causing an uneven anode layer 140 formed subsequently. A material of the first planarization layer 110 may include an organic insulating material. For example, the first planarization layer 110 is made of polyimide.

The second source-drain metal layer 120 is located on a side of the first planarization layer 110 away from the substrate 10, and is used to connect the first source-drain metal layer 80 and the anode layer 140. The second source-drain metal layer 120 may be made of the same material as the first source-drain metal layer 80.

The second planarization layer 130 is located on a side of the second source-drain metal layer 120 away from the substrate 10, and is used to make a surface of the second source-drain metal layer 120 away from the substrate 10 planar. The second planarization layer 130 may be made of the same material as the first planarization layer 110.

The anode layer 140 is located on a side of the second planarization layer 130 away from the substrate 10. The anode layer 140 includes a plurality of anodes 141. A material of the anode layer 140 may include indium tin oxide (ITO).

The pixel definition layer 150 is located on a side of the anode layer 140 away from the substrate 10. The pixel definition layer 150 is provided therein with a plurality of openings 151. The pixel definition layer 150 may be made of the same material as the first planarization layer 110.

The light-emitting functional layer 160 is located on a side of the anode layer 140 away from the substrate 10. Portions of the light-emitting functional layer 160 are located in the openings 151, and are connected to the anode layer 140.

The cathode layer 170 is located on a side of the pixel definition layer 150 away from the substrate 10, and is of a continuous whole-layer structure. Portions of the anode 141, the light-emitting functional layer 160 and the cathode layer 170, whose orthogonal projections on the substrate 10 overlap, constitute a light-emitting device 1. The anode 141 and the cathode layer 170 respectively inject holes and electrons into the light-emitting functional layer 160, and light is emitted when the excitons generated by the combination of holes and electrons transition from an excited state to a ground state.

The encapsulation layer 180 is located on a side of the cathode layer 170 away from the substrate 10, and covers the cathode layer 170. The encapsulation layer 180 may be an encapsulation film. The number of encapsulation films included in the encapsulation layer 180 is not limited in the embodiments of the present disclosure. In some embodiments, the encapsulation layer 180 may include one encapsulation film, or may include two or more encapsulation films that are stacked. For example, the encapsulation layer 180 includes a first inorganic encapsulation layer 181, a first organic encapsulation layer 182 and a second inorganic encapsulation layer 183 that are stacked in a direction perpendicular to the substrate 10 and away from the substrate 10. A material of the first inorganic encapsulation layer 181 and a material of the second inorganic encapsulation layer 183 each include any one or more of silicon nitride, silicon oxynitride or silicon oxide. A material of the first organic encapsulation layer 182 includes a polymer resin, such as polyimide.

In some embodiments, as shown in FIG. 4, the display panel 400 further includes a touch insulating layer 190, a second organic encapsulation layer 210, and a touch protective layer 220. The touch insulating layer 190 is located on a side of the second inorganic encapsulation layer 183 away from the substrate 10. The second organic encapsulation layer 210 is located on a side of the touch insulating layer 190 away from the substrate 10. The touch protective layer 220 is located on a side of the second organic encapsulation layer 210 away from the substrate 10.

In some embodiments, FIG. 4 is a structural diagram of a display panel including a first isolation structure, and as shown in FIGS. 3 and 4, the display panel 400 further includes first isolation structure(s) 2. The first isolation structure(s) 2 are located on the substrate 10 and are arranged around the through hole 4001. As shown in FIG. 5, the first isolation structure 2 includes a first isolation portion 201 and a second isolation portion 202 that are stacked. The first isolation portion 201 is located between the second isolation portion 202 and the substrate 10, and an edge portion of a surface, close to the substrate 10, of the second isolation portion 202 extends beyond the first isolation portion 201 (an orthogonal projection of the first isolation portion 201 on the substrate 10 is located within an orthogonal projection of the surface, close to the substrate 10, of the second isolation portion 202 on the substrate 10). In this way, the first isolation portion 201 and the second isolation portion 202 constitute a roof structure. In a case where the first isolation structure 2 is not bonded to other film layers, an area outside the first isolation portion 201 and below the second isolation portion 202 in the first isolation structure 2 is empty.

As shown in FIGS. 3 and 4, the cathode layer 170 extends to the isolation region 101 and covers the isolation region 101. During the process of depositing the material of the cathode layer 170, since the area outside the first isolation portion 201 and below the second isolation portion 202 is empty, the material of the cathode layer 170 cannot be attached in this area, and the cathode layer 170 will be disconnected in this area. The first isolation structure 2 divides a part of the cathode layer 170 in the isolation region 101 into a first sub-portion 171 and a second sub-portion 172. In a direction perpendicular to a boundary of the through hole 4001, the first sub-portion 171 and the second sub-portion 172 are alternately arranged. The first sub-portion 171 is located on a side of the second isolation portion 202 away from the substrate 10, and the second sub-portion 172 is located on a side of the first isolation portion 201. In the isolation region 101, the first isolation structure 2 causes the cathode layer 170 to be disconnected, thereby reducing the risk of water vapor being transmitted to the display region 102 through the cathode layer 170 via the through hole 4001 and improving the service life of the display panel 400. In a case where the boundary of the through hole 4001 is a curve, the description of perpendicular to the boundary of the through hole 4001 means perpendicular to a tangent of the curve. In a case where the boundary of the through hole 4001 is a straight line, the description of perpendicular to the boundary of the through hole 4001 means perpendicular to the straight line.

During the process of depositing the material of the cathode layer 170, the material of the cathode layer 170 will be deposited in the area outside the first isolation portion 201 and below the second isolation portion 202 in the first isolation structure 2, so that the first sub-portion 171 may be in contact with the first isolation portion 201. The first isolation portion 201 is made of an insulating material. Therefore, the first isolation portion 201 will electrically insulate second sub-portions 172 that are respectively located on two sides of the first isolation structure 2, and the part of the cathode layer 170 located in the isolation region 101 is in disconnection. When the display region 102 is powered on, the risk of leakage from the display region 102 to the first hole 1010 is reduced.

During the reliability test, chemical substances such as potassium ions (K⁺) and silver ions (Ag⁺) in the pressure-sensitive conductive adhesive (the first pressure-sensitive conductive adhesive 300 and the second pressure-sensitive conductive adhesive 500) will enter the display panel 400 along a sidewall of the first hole 1010, and also enter the isolation region 101 through the cathode layer 170. When the display region 102 is powered on, the part of the cathode layer 170 located in the isolation region 101 is in disconnection. Therefore, the part of the cathode layer 170 located in the isolation region 101 is not charged, which may ameliorate the problem of chemical reaction between the above-mentioned chemical substances and the first inorganic encapsulation layer 181, and reduce the risk of failure of the first inorganic encapsulation layer 181.

In some embodiments, as shown in FIGS. 4 and 5, the first isolation portion 201 and the first planarization layer 110 are arranged in the same layer. In this way, the first isolation portion 201 and the first planarization layer 110 may be formed by a single patterning process, thus reducing the number of patterning times, saving manufacturing costs and improving the manufacturing efficiency.

In some other embodiments, FIG. 6 is a structural diagram of a first isolation portion including a first sub-layer and a second sub-layer. As shown in FIG. 6, the first isolation portion 201 includes a first sub-layer 2011 and a second sub-layer 2012 that are stacked in the direction away from the substrate 10, the first sub-layer 2011 and the passivation layer 90 are arranged in the same layer, and the second sub-layer 2012 and the first planarization layer 110 are arranged in the same layer. In this way, a distance between the first isolation portion 201 and the second isolation portion 202 is large, which facilitates the disconnection of the cathode layer 170 and may reduce the risk of water vapor being transmitted by the cathode layer 170 to the display region 102 via the through hole 4001. Therefore, the service life of the display panel 400 is improved.

In some embodiments, as shown in FIG. 6, the second isolation portion 202 and the second source-drain metal layer 120 are arranged in the same layer. In this way, the second isolation portion 202 and the second source-drain metal layer 120 may be formed through one patterning process, thereby reducing the number of patterning times, saving the manufacturing costs and improving the manufacturing efficiency.

In some embodiments, the second source-drain metal layer 120 includes a first metal layer, a second metal layer, and a third metal layer that are stacked in the direction away from the substrate 10. For example, the first metal layer and the third metal layer may be made of titanium, and the second metal layer may be made of aluminum.

As shown in FIG. 5, the second isolation portion 202 includes a first pad layer 2021, a second pad layer 2022 and a third pad layer 2023 that are stacked in the direction away from the substrate 10. The first pad layer 2021 and the first metal layer are arranged in the same layer, the second pad layer 2022 and the second metal layer are arranged in the same layer, and the third pad layer 2023 and the third metal layer are arranged in the same layer. In this way, the first pad layer 2021 and the first metal layer may be formed through one patterning process, the second pad layer 2022 and the second metal layer may be formed through one patterning process, and the third pad layer 2023 and the third metal layer may be formed through one patterning process, thereby reducing the number of patterning times, saving the manufacturing costs and improving the manufacturing efficiency.

As shown in FIG. 5, an edge portion of the first pad layer 2021 extends beyond the first isolation portion 201. In this way, the first pad layer 2021 and the first isolation portion 201 constitute a roof structure. An edge portion of the third pad layer 2023 extends beyond the second pad layer 2022. In this way, the third pad layer 2023 and the second pad layer 2022 constitute a roof structure. The first isolation structure 2 includes two stacked roof structures. The cathode layer 170 can be disconnected as long as the cathode layer 170 is disconnected at at least one of the roof structures, thereby reducing the risk of water vapor and oxygen entering the display region 102.

In some embodiments, as shown in FIG. 5, an edge portion of the first pad layer 2021 extends beyond the second pad layer 2022. An orthogonal projection of the second isolation portion 202 on a reference plane is in a shape of Chinese character “ [symbol] ”. The reference plane is perpendicular to the substrate 10 and perpendicular to the boundary of the first hole 1010.

In some embodiments, as shown in FIGS. 4 and 5, the first inorganic encapsulation layer 181 also extends to the isolation region 101 and covers the isolation region 101. The first inorganic encapsulation layer 181 is in contact with a side surface of the first isolation portion 201, a surface of a portion of the first pad layer 2021 extending beyond the first isolation portion 201, a side surface of the second pad layer 2022, and a surface of a portion of the third pad layer 2023 extending beyond the second pad layer 2022.

In some embodiments, as shown in FIG. 4, the display panel 400 includes a plurality of first isolation structures 2, and the plurality of first isolation structures 2 are arranged at intervals in the direction perpendicular to the boundary of the through hole 4001. In this way, the cathode layer 170 is disconnected at at least one of the first isolation structures 2, so that the part of the cathode layer 170 located in the isolation region 101 is in disconnection, which may reduce the risk of failure of the first inorganic encapsulation layer 181.

In some embodiments, as shown in FIG. 4, the display panel 400 further includes a barrier wall structure 3. The barrier wall structure 3 is located in the isolation region 101 and is arranged around the through hole 4001. The barrier wall structure 3 is used for blocking water and oxygen, thereby improving the water and oxygen blocking performance of the encapsulation layer 180. During the process of fabricating the first organic encapsulation layer 182, the barrier wall structure is further used for blocking ink, so that the first organic encapsulation layer 182 is located on a side of the barrier wall structure 3 away from the through hole 4001. As a result, the second inorganic encapsulation layer 183 can completely cover the first organic encapsulation layer 182, thereby ameliorating the problem that water and oxygen corroding the first organic encapsulation layer 182 causes the failure of the first organic encapsulation layer 182.

As shown in FIGS. 3, 4 and 5, at least one first isolation structure 2 is located on a side of the barrier wall structure 3 close to the through hole 4001, and at least one first isolation structure 2 is located on a side of the barrier wall structure 3 away from the through hole 4001. The first isolation structure(s) 2 located on the side of the barrier wall structure 3 away from the through hole 4001 makes a surface of the first inorganic encapsulation layer 181 away from the substrate 10 uneven. During the process of fabricating the first organic encapsulation layer 182, the flow rate of the ink is reduced due to the uneven surface, thereby reducing the risk of the ink crossing the barrier wall structure 3.

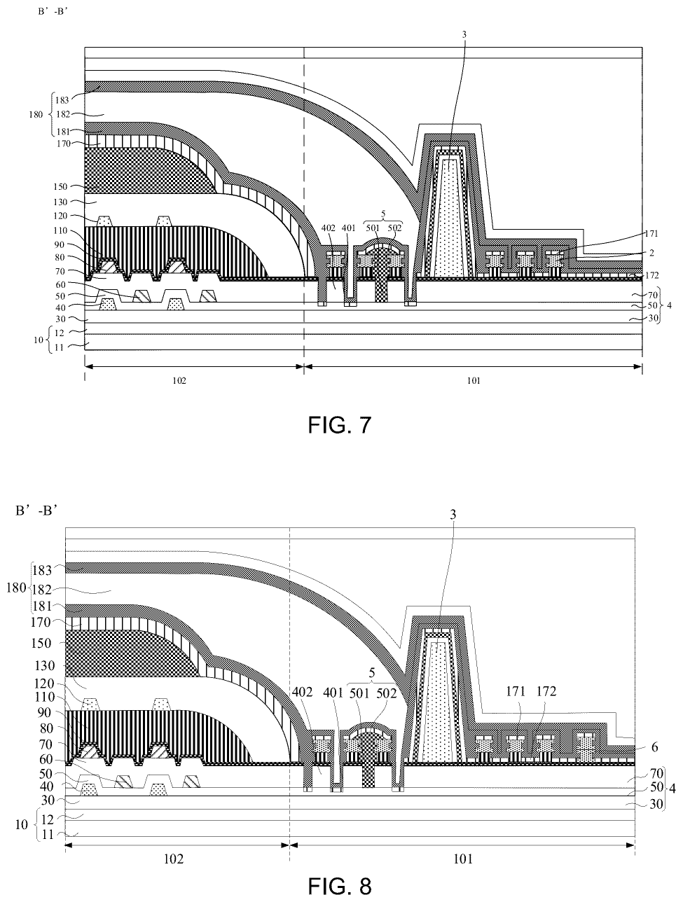

In some embodiments, FIG. 7 is a structural diagram of a display panel including separation grooves. As shown in FIG. 7, the first gate insulating layer 30, the second gate insulating layer 50 and the interlayer dielectric layer 70 are stacked to constitute an inorganic insulating layer 4, and the inorganic insulating layer 4 extends to the isolation region 101 and covers the isolation region 101. A surface, away from the substrate 10, of the inorganic insulating layer 4 is provided with a plurality of separation grooves 401, and the plurality of separation grooves 401 surround the through hole 4001. The plurality of separation grooves 401 are located in the isolation region 101, and on are located the side of the barrier wall structure 3 away from the through hole 4001. The plurality of separation grooves 401 may make the surface of the first inorganic encapsulation layer 181 away from the substrate 10 more uneven, so that the flow rate of the ink is reduced more quickly, and the risk of the ink overflowing the barrier wall structure 3 is reduced.

A portion of the inorganic insulating layer 4 between two adjacent separation grooves 401 constitutes a protrusion 402. The first isolation structure 2 located on the side of the barrier wall structure 3 away from the through hole 4001 is located on a side of the protrusion 402 away from the substrate 10. An orthogonal projection of the second isolation portion 202 on the substrate 10 coincides with an orthogonal projection of the protrusion 402 on the substrate 10. In this way, during the process of depositing the material of the cathode layer 170, the material of the cathode layer 170 will be deposited in the separation groove 401. That is, the formed second sub-portion 172 is located in the separation groove 401. A distance between the first sub-portion 171 and the second sub-portion 172 is large, which facilitates the disconnection of the cathode layer 170.

In some embodiments, FIG. 7 is a structural diagram of a display panel including a buffer structure. As shown in FIG. 7, the display panel 400 further includes a buffer structure 5. The buffer structure 5 is located on the side of the barrier wall structure 3 away from the through hole 4001, and is arranged around the through hole 4001. The buffer structure 5 includes a first buffer portion 501 and a second buffer portion 502 that are stacked in the direction away from the substrate 10. The first buffer portion 501 is partially located in a separation groove 401 and partially located between two adjacent first isolation structures 2. The second buffer portion 502 is located on a side of the first isolation structure 2 away from the substrate 10 and is connected to the first buffer portion 501. The buffer structure 5 makes the surface of the first inorganic encapsulation layer 181 away from the substrate 10 more uneven, so that the flow rate of the ink is reduced more quickly, and the risk of the ink overflowing the barrier wall structure 3 is reduced.

In some embodiments, the first source-drain metal layer 80 includes a fourth metal layer, a fifth metal layer, and a sixth metal layer that are stacked in the direction away from the substrate. The first source-drain metal layer 80 and the second source-drain metal layer 120 may be made of the same material. For example, the fourth metal layer and the sixth metal layer may be made of titanium, and the fifth metal layer may be made of aluminum.

FIG. 8 is a structural diagram of a display panel including a second isolation structure. As shown in FIG. 8, the display panel 400 further includes a second isolation structure 6. The second isolation structure 6 is located in the isolation region 101 and is arranged around the through hole 4001. As shown in FIG. 8, the second isolation structure 6 includes a third isolation portion 601 and a fourth isolation portion 602 that are stacked in the direction away from the substrate 10. The third isolation portion 601 includes a fourth pad layer 6011, a fifth pad layer 6012 and a sixth pad layer 6013 that are stacked in the direction away from the substrate 10. The fourth isolation portion 602 includes a seventh pad layer 6014, an eighth pad layer 6015 and a ninth pad layer 6016 that are stacked in the direction away from the substrate 10.

The fourth pad layer 6011 and the fourth metal layer are arranged in the same layer. The fifth pad layer 6012 and the fifth metal layer are arranged in the same layer. The sixth pad layer 6013 and the sixth metal layer are arranged in the same layer. The seventh pad layer 6014 and the first metal layer are arranged in the same layer. The eighth pad layer 6015 and the second metal layer are arranged in the same layer. The ninth pad layer 6016 and the third metal layer are arranged in the same layer. In this way, the fourth pad layer 6011 and the fourth metal layer may be formed through one patterning process, the fifth pad layer 6012 and the fifth metal layer may be formed through one patterning process, the sixth pad layer 6013 and the sixth metal may be formed through one patterning process, the seventh pad layer 6014 and the first metal layer may be formed through one patterning process, the eighth pad layer 6015 and the second metal layer may be formed through one patterning process, and the ninth pad layer 6016 and the third metal layer may be formed through one patterning process, thereby reducing the number of patterning times, saving the manufacturing costs and improving the manufacturing efficiency.

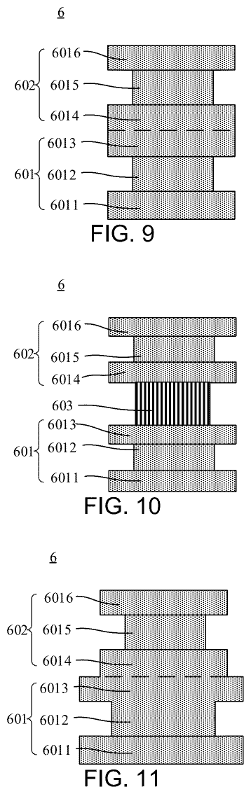

As shown in FIG. 9, an edge portion of the sixth pad layer 6013 extends beyond the fifth pad layer 6012. That is, the sixth pad layer 6013 and the fifth pad layer 6012 constitute a roof structure. An edge portion of the ninth pad layer 6016 extends beyond the eighth pad layer 6015. That is, the ninth pad layer 6016 and the eighth pad layer 6015 constitute a roof structure. That is to say, the second isolation structure 6 includes two stacked roof structures. During the process of depositing the material of the cathode layer 170, at least one roof structure in the second isolation structure 6 will cause the disconnection of the cathode layer 170 at the second isolation structure 6, thereby reducing the risk of water vapor intruding into the display region through the cathode layer 170.

In some embodiments, as shown in FIG. 9, the sixth pad layer 6013 and the seventh pad layer 6014 are made of the same material; a thickness of the fourth pad layer 6011 is equal to a thickness of the sixth pad layer 6013; a thickness of the seventh pad layer 6014 is equal to a thickness of the ninth pad layer 6016; and there is no visible boundary line between the sixth pad layer 6013 and the seventh pad layer 6014. Therefore, a distance between the fifth pad layer 6012 and the eighth pad layer 6015 is twice the thickness of the fourth pad layer 6011, and twice the thickness of the ninth pad layer 6016.

In some embodiments, as shown in FIG. 10, the second isolation structure 6 further includes a fifth isolation portion 603 between the third isolation portion 601 and the fourth isolation portion 602. An edge portion of the seventh pad layer 6014 extends beyond the fifth isolation portion 603. That is, the seventh pad layer 6014 and the fifth isolation portion 603 constitute a roof structure. In this way, the second isolation structure 6 includes three roof structures, so that the risk of water vapor intruding into the display region through the cathode layer 170 is further reduced.

For example, the fifth isolation portion 603 and the first planarization layer 110 are arranged in the same layer. For another example, the fifth isolation portion 603 is arranged in the same layer as the first planarization layer 110, and is arranged in the same layer as the passivation layer 90. In this case, as for the structure of the fifth isolation portion 603, reference can be made to the structure of the first isolation portion 201 including the first sub-layer 2011 and the second sub-layer 2012. For yet another example, the fifth isolation portion 603 and the passivation layer 90 are arranged in the same layer.

In some embodiments, FIG. 9 is a diagram showing a structure in which the fourth pad layer 6011, the sixth pad layer 6013, the seventh pad layer 6014 and the ninth pad layer 6016 coincide with each other. As shown in FIG. 9, orthogonal projections, on the substrate 10, of the fourth pad layer 6011, the sixth pad layer 6013, the seventh pad layer 6014 and the ninth pad layer 6016 coincide with each other. In this way, the second isolation structure 6 has a large size in a direction perpendicular to the substrate 10, so that a distance between the first sub-portion 171 and the second sub-portion 172 is large, which is more conducive to disconnecting the cathode layer 170.

In some other embodiments, FIG. 11 is a diagram showing a structure in which the seventh pad layer 6014 is located within a range of the sixth pad layer 6013. As shown in FIG. 11, orthogonal projections, on the substrate 10, of the fourth pad layer 6011 and the sixth pad layer 6013 coincide with each other; orthogonal projections, on the substrate 10, of the seventh pad layer 6014 and the ninth pad layer 6016 coincide with each other; and an orthogonal projection of the seventh pad layer 6014 on the substrate 10 is located within an orthogonal projection of the sixth pad layer 6013 on the substrate 10, and there is a distance between boundaries of orthogonal projections, on the substrate 10, of the seventh pad layer 6014 and the sixth pad layer 6013. In this way, during the process of depositing the material of the cathode layer 170, the cathode layer 170 will be disconnected once between the fourth pad layer 6011 and the sixth pad layer 6013, and will be disconnected again between the seventh pad layer 6014 and the ninth pad layer 6016. The cathode layer 170 can be disconnected if the disconnection is successful once, thereby improving the reliability of dividing the cathode layer 170 by the second isolation structure 6.

The inventors have found that when the first inorganic encapsulation layer 181 is bonded to a side surface of the fifth pad layer 6012 and is bonded to a surface of a portion of the sixth pad layer 6013 extending beyond the fifth pad layer 6012, the first inorganic encapsulation layer 180 has good adhesion to the second isolation structure 6. That is, the first inorganic encapsulation layer 181 is bonded more firmly. In other words, when the first inorganic encapsulation layer 181 is bonded to a side surface and a lower surface of the roof structure, the roof structure makes the first inorganic encapsulation layer 181 bonded more firmly, thereby reducing the risk of separation between the first inorganic encapsulation layer 181 and the cathode layer 170.

In some embodiments, as shown in FIG. 8, the first inorganic encapsulation layer 181 is in contact with the side surface of the fifth pad layer 6012, the surface of the portion of the sixth pad layer 6013 extending beyond the fifth pad layer 6012, a side surface of the eighth pad layer 6015, and a surface of a portion of the ninth pad layer 6016 extending beyond the eighth pad layer 6015. The first inorganic encapsulation layer 181 is bonded to side surfaces and lower surfaces of the two roof structures in the second isolation structure 6. Therefore, the first inorganic encapsulation layer 181 may be more firmly bonded to the second isolation structure 6. In the case where the second isolation structure 6 further includes the fifth isolation portion 603, the first inorganic encapsulation layer 181 is further in contact with a side surface of the fifth isolation portion 603 and a surface of a portion of the seventh pad layer 6014 extending beyond the fifth isolation portion 603. That is, the first inorganic encapsulation layer 181 is bonded to side surfaces and lower surfaces of the three roof structures in the second isolation structure 6. Therefore, the first inorganic encapsulation layer 181 and the second isolation structure 6 may be bonded more firmly.

The inventors have also found that the larger the height of the fifth isolation portion 603, the stronger the bonding between the fifth isolation portion 603 and the first inorganic encapsulation layer 181. The fifth isolation portion 603 is arranged in the same layer as the first planarization layer 110, and is arranged in the same layer as the passivation layer 90. In the embodiments of the present disclosure, the fifth isolation portion 603 includes two film layers, so that the fifth isolation portion 603 has a large height, and the first inorganic encapsulation layer 181 is bonded more firmly.

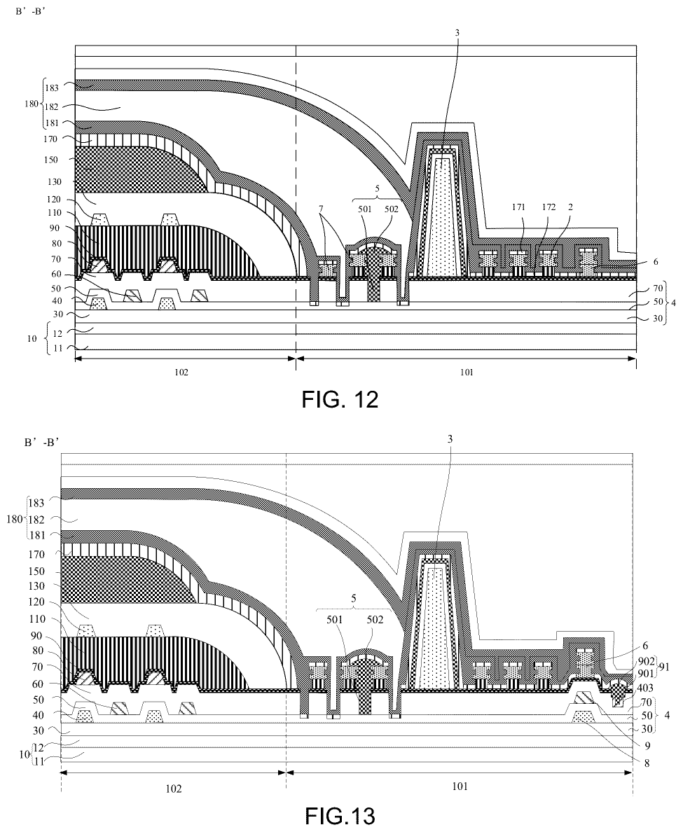

In some embodiments, as shown in FIG. 12, the display panel 400 further includes third isolation structure(s) 7. The third isolation structure 7 may be the first isolation structure 2, or may be an isolation structure in the related art. A detailed structure of the isolation structure in the related art will not be described herein. Alternatively, the third isolation structures 7 may include the first isolation structure 2 and the isolation structure in the related art.

As shown in FIG. 12, at least one third isolation structure 7 is disposed on the side of the barrier wall structure 3 close to the through hole 4001, and the second isolation structure 6 is closer to the through hole 4001 than the third isolation structure 7. In this way, the first inorganic encapsulation layer 181 on a side of the third isolation structure 7 close to the through hole 4001 is bonded more firmly, which may ameliorate the problem that the first inorganic encapsulation layer 181 at the edge of the through hole 4001 is peeled off from the cathode layer 170 to cause the peeling to spread to the display region 102, and reduce the risk of the peeling spreading to the display region 102 which causes the first inorganic encapsulation layer 181 to damage the third isolation structure 7.

In some embodiments, FIG. 13 is a structural diagram of a display panel including a first pad block and a second pad block. As shown in FIG. 13, the display panel further includes a first pad block 8 and a second pad block 9. The first pad block 8 is arranged in the same layer as the first gate metal layer 40. The first pad block 8 is located on a side of the barrier wall structure 3 close to the through hole 4001, and is arranged around the through hole 4001. An orthogonal projection of the first pad block 8 on the substrate 10 overlaps with an orthogonal projection of the second isolation structure 6 on the substrate. The first pad block 8 may increase a distance between an end of the second isolation structure 6 away from the substrate 10 and the substrate 10, and may enhance the water and oxygen blocking performance of the second isolation structure 6.

The second pad block 9 is arranged in the same layer as the second gate metal layer 60. The second pad block 9 is located on a side of the barrier wall structure 3 close to the through hole 4001, and is arranged around the through hole 4001. An orthogonal projection of the second pad block 9 on the substrate overlaps with the orthogonal projection of the second isolation structure 6 on the substrate. Due to the second pad block 9, the distance between the end of the second isolation structure 6 away from the substrate 10 and the substrate 10 may be further increased, and the water and oxygen blocking performance of the second isolation structure 6 may be further enhanced.

It will be understood that the orthogonal projection of the first pad block 8 on the substrate 10 may overlap with an orthogonal projection, on the substrate, of a first isolation structure 2 which is located on a side of the barrier wall structure 3 close to the through hole 4001, and the orthogonal projection of the second pad block 9 on the substrate 10 overlaps with the orthogonal projection of this first isolation structure 2 on the substrate. The first pad block 8 and the second pad block 9 may increase a distance between an end of the first isolation structure 2 away from the substrate 10 and the substrate 10, and improve the water and oxygen blocking performance of the first isolation structure 2.

In the related art, during the cutting process of the through hole, a cutting crack is created due to cutting stress and will extend to the display region through the inorganic insulating layer, resulting in a decrease in the qualification rate of the display panel and an increase in the manufacturing costs of the display panel.

In some embodiments, FIG. 13 is a structural diagram of a display panel which is provided with a groove. As shown in FIG. 13, the surface of the inorganic insulating layer 4 away from the substrate 10 is provided with a groove 403. The groove 403 is located in the isolation region 101 and is arranged around the through hole 4001. When the cutting crack spreads to the groove 403, no inorganic material exists in the groove 403, and the cutting crack cannot extend to the display region 102 through the groove 403, so that the groove 403 reduces the risk of the cutting crack extending to the display region 102.

The groove 403 is closer to the through hole 4001 than both the second isolation structure 6 and the third isolation structure. In this way, the cutting crack will not affect the second isolation structure 6 and the third isolation structure 7, thereby reducing the risk of damage to the second isolation structure 6 and the third isolation structure.

In some embodiments, FIG. 13 is a structural diagram of a display panel including a stress absorption structure. As shown in FIG. 13, the display panel further includes a stress absorption structure 91, and the stress absorption structure 91 is partially located in the groove 403. The stress absorption structure 91 can absorb the cutting stress and reduce the risk of the cutting crack, created due to the cutting stress, extending to the display region 102.

Since metal or organic material has the property of absorbing stress and dissipating the stress, a material of the stress absorption structure includes metal and/or organic material. As shown in FIG. 13, the stress absorption structure 91 includes a first stress portion 901 and a second stress portion 902 that are stacked in the direction perpendicular to the substrate 10. The first stress portion 901 is arranged in the same layer as the first source-drain metal layer 80, and the second stress portion 902 is arranged in the same layer as the pixel definition layer 150.

In the case where the display panel 400 includes the first pad block 8 and the second pad block 9, the first pad block 8 and the second pad block 9 may also absorb the stress and reduce the risk of the cutting crack extending to the display region 102.

In the description of the specification, specific features, structures, materials or characteristics may be combined in any suitable manner in any one or more embodiments or examples.

The foregoing descriptions are merely specific implementation manners of the present disclosure, but the protection scope of the present disclosure is not limited thereto. Any changes or replacements that a person skilled in the art could conceive of within the technical scope of the present disclosure shall be included in the protection scope of the present disclosure. Therefore, the protection scope of the present disclosure shall be subject to the protection scope of the claims.

What is claimed is:

1. A display panel, having a through hole and an isolation region surrounding the through hole, the display panel comprising:
a substrate;
at least one first isolation structure located on the substrate and located in the isolation region, and being arranged around the through hole, wherein a first isolation structure includes a first isolation portion and a second isolation portion that are stacked; the first isolation portion is located between the second isolation portion and the substrate; an edge portion, close to a surface of the substrate, of the second isolation portion extends beyond the first isolation portion; and the first isolation portion is made of an insulating material; and
a cathode layer located on the substrate and extending to the isolation region, wherein in the isolation region, the first isolation structure divides the cathode layer into a first sub-portion and a second sub-portion; in a direction perpendicular to a boundary of the through hole, the first sub-portion and the second sub-portion are alternately arranged; the first sub-portion is located on a side of the second isolation portion away from the substrate; and the second sub-portion is located on a side of the first isolation portion.

2. The display panel according to claim 1, further comprising:
a first planarization layer located between the substrate and the cathode layer;
wherein the first isolation portion and the first planarization layer are arranged in a same layer.

3. The display panel according to claim 1, further comprising:
a passivation layer located between the cathode layer and the substrate; and
a first planarization layer located between the passivation layer and the cathode layer;
wherein the first isolation portion includes a first sub-layer and a second sub-layer that are stacked in a direction away from the substrate; the first sub-layer and the passivation layer are arranged in a same layer; and the second sub-layer and the first planarization layer are arranged in a same layer.

4. The display panel according to claim 1, further comprising:
a second source-drain metal layer located between the cathode layer and the substrate;
wherein the second isolation portion and the second source-drain metal layer are arranged in a same layer.

5. The display panel according to claim 4, wherein
the second source-drain metal layer includes a first metal layer, a second metal layer and a third metal layer that are stacked in a direction away from the substrate;
the second isolation portion includes a first pad layer, a second pad layer and a third pad layer that are stacked in the direction away from the substrate; the first pad layer and the first metal layer are arranged in a same layer; the second pad layer and the second metal layer are arranged in a same layer; the third pad layer and the third metal layer are arranged in a same layer;
wherein an edge portion of the first pad layer extends beyond the first isolation portion; and an edge portion of the third pad layer extends beyond the second pad layer.

6. The display panel according to claim 5, wherein the edge portion of the first pad layer extends beyond the second pad layer.

7. The display panel according to claim 5, further comprising:
a first inorganic encapsulation layer located on a side of the cathode layer away from the substrate and extending to the isolation region, wherein the first inorganic encapsulation layer is in contact with a side surface of the first isolation portion, a surface of a portion of the first pad layer extending beyond the first isolation portion, a side surface of the second pad layer, and a surface of a portion of the third pad layer extending beyond the second pad layer.

8. The display panel according to claim 1, wherein the at least one first isolation structure includes a plurality of first isolation structures, wherein the plurality of first isolation structures are arranged at intervals in the direction perpendicular to the boundary of the through hole.

9. The display panel according to claim 8, further comprising:
a barrier wall structure located in the isolation region and arranged around the through hole;
wherein at least one of the plurality of first isolation structures is located on a side of the barrier wall structure close to the through hole, and at least one of the plurality of first isolation structures is located on a side of the barrier wall structure away from the through hole.

10. The display panel according to claim 9, further comprising:
an inorganic insulating layer located between the substrate and the first isolation structure and extending to the isolation region, wherein a surface of the inorganic insulating layer away from the substrate is provided with a plurality of separation grooves; the plurality of separation grooves are arranged around the through hole, are located in the isolation region, and are located on the side of the barrier wall structure away from the through hole; a portion of the inorganic insulating layer located between two adjacent separation grooves constitutes a protrusion;
wherein a first isolation structure located on the side of the barrier wall structure away from the through hole is located on a side of the protrusion away from the substrate.

11. The display panel according to claim 1, further comprising:
a first source-drain metal layer located between the cathode layer and the substrate, the first source-drain metal layer including a fourth metal layer, a fifth metal layer and a sixth metal layer that are stacked in a direction away from the substrate;
a second source-drain metal layer located between the first source-drain metal layer and the cathode layer, the second source-drain metal layer including a first metal layer, a second metal layer and a third metal layer that are stacked in the direction away from the substrate; and
one or more second isolation structures located in the isolation region and arranged around the through hole, wherein a second isolation structure among the one or more second isolation structures includes a third isolation portion and a fourth isolation portion that are stacked in the direction away from the substrate; the third isolation portion includes a fourth pad layer, a fifth pad layer and a sixth pad layer; the fourth isolation portion includes a seventh pad layer, an eighth pad layer and a ninth pad layer;
wherein the fourth pad layer and the fourth metal layer are arranged in a same layer; the fifth pad layer and the fifth metal layer are arranged in a same layer; the sixth pad layer and the sixth metal layer are arranged in a same layer; the seventh pad layer and the first metal layer are arranged in a same layer; the eighth pad layer and the second metal layer are arranged in a same layer; and the ninth pad layer and the third metal layer are arranged in a same layer;
an edge portion of the sixth pad layer extends beyond the fifth pad layer; and an edge portion of the ninth pad layer extends beyond the eighth pad layer.

12. The display panel according to claim 11, further comprising:
a passivation layer located between the first source-drain metal layer and the second source-drain metal layer; and
a first planarization layer located between the passivation layer and the second source-drain metal layer;
wherein the second isolation structure further includes a fifth isolation portion disposed between the third isolation portion and the fourth isolation portion; the fifth isolation portion is arranged in a same layer as the first planarization layer, and/or arranged in a same layer as the passivation layer;
an edge portion of the seventh pad layer extends beyond the fifth isolation portion.

13. The display panel according to claim 11, further comprising:
a first inorganic encapsulation layer located on a side of the cathode layer away from the substrate and extending to the isolation region, wherein the first inorganic encapsulation layer is in contact with a side surface of the fifth pad layer, a surface of a portion of the sixth pad layer extending beyond the fifth pad layer, a side surface of the eighth pad layer, and a surface of a portion of the ninth pad layer extending beyond the eighth pad layer;
the second isolation structure further includes a fifth isolation portion disposed between the third isolation portion and the fourth isolation portion, and the first inorganic encapsulation layer is further in contact with a side surface of the fifth isolation portion and a surface of a portion of the seventh pad layer extending beyond the fifth isolation portion.

14. The display panel according to claim 11, further comprising:
a barrier wall structure located in the isolation region and arranged around the through hole; wherein
at least one second isolation structure of the one or more second isolation structures is disposed on a side of the barrier wall structure close to the through hole.

15. The display panel according to claim 14, further comprising:
at least one third isolation structure being disposed on the side of the barrier wall structure close to the through hole, wherein the at least one second isolation structure is closer to the through hole than the at least one third isolation structure.

16. The display panel according to claim 11, wherein orthogonal projections, on the substrate, of the fourth pad layer, the sixth pad layer, the seventh pad layer and the ninth pad layer coincide with each other.

17. The display panel according to claim 11, further comprising:
a barrier wall structure located in the isolation region and arranged around the through hole;
a first gate metal layer and a second gate metal layer that are stacked and disposed between the substrate and the first source-drain metal layer; and
a first pad block which is arranged in a same layer as the first gate metal layer, is located on a side of the barrier wall structure close to the through hole, and is arranged around the through hole, wherein an orthogonal projection of the first pad block on the substrate overlaps with an orthogonal projection of the second isolation structure on the substrate; and/or
a second pad block which is arranged in a same layer as the second gate metal layer, is located on the side of the barrier wall structure close to the through hole, and is arranged around the through hole, wherein an orthogonal projection of the second pad block on the substrate overlaps with the orthogonal projection of the second isolation structure on the substrate.

18. A display apparatus, comprising:
the display panel according to claim 1; and
a cover plate located on a side of the first isolation structure in the display panel away from the substrate.

19. The display apparatus according to claim 18, further comprising:
a second pressure-sensitive conductive adhesive located between the display panel and the cover plate, the second pressure-sensitive conductive adhesive covering the display panel.

20. The display panel according to claim 2, further comprising:
a second source-drain metal layer located between the cathode layer and the substrate;
wherein the second isolation portion and the second source-drain metal layer are arranged in a same layer.
